(19) United States
(12) Patent Application Publication
(10) Pub. No.: US 2009/0132879 A1
(43) Pub. Date: May 21, 2009

(54) MULTIPLEXING OF SCAN INPUTS AND SCAN OUTPUTS ON TEST PINS FOR TESTING OF AN INTEGRATED CIRCUIT

(75) Inventor: Ramesh Gangappa, Bangalore (IN)

Correspondence Address: QUALCOMM INCORPORATED, 5775 MOREHOUSE DR., SAN DIEGO, CA, 92121, US

(73) Assignee: QUALCOMM, INCORPORATED, San Diego, CA (US)

(21) Appl. No.: 12/191,053

(22) Filed: Aug. 13, 2008

Related U.S. Application Data
(60) Provisional application No. 60/988,961, filed on Nov. 19, 2007.
(60) Provisional application No. 60/989,290, filed on Nov. 20, 2007.

(51) Int. Cl. G01R 31/3177; G06F 11/25

(52) U.S. Cl. 714/729; 714/726; 714/731; 714/E11.155

(57) ABSTRACT

Techniques for efficiently performing scan tests are described. In an aspect, a single test pin may be used for both a scan input and a scan output for a scan chain. This multiplexing may reduce test costs and provide other benefits. In one design, an integrated circuit (IC) die includes a scan chain and an input/output (I/O) circuit. The I/O circuit is coupled between the scan chain and a single pad for a single test pin. The I/O circuit multiplexes a scan input and a scan output for the scan chain, provides the scan input from the pad to the scan chain during an input phase of a clock cycle, and provides the scan output from the scan chain to the pad during an output phase of the clock cycle. A bi-directional control signal controls the multiplexing of the scan input and the scan output by the I/O circuit.

### CLAIM OF PRIORITY UNDER 35 U.S.C. §119

The present Application for Patent claims priority to Provisional U.S. Application Ser. No. 60/988,961, entitled “METHOD AND APPARATUS FOR MULTIPLEXING SCAN PINS,” filed Nov. 19, 2007, and Provisional U.S. Application Ser. No. 60/989,290, entitled “METHOD AND APPARATUS FOR MULTIPLEXING SCAN IN AND SCAN OUT IN XOR COMPRESSION MODE,” filed Nov. 20, 2007, both assigned to the assignee hereof and expressly incorporated herein by reference.

### BACKGROUND

I. Field

The present disclosure relates generally to electronics, and more specifically to techniques for testing integrated circuits (ICs).

II. Background

Integrated circuits are widely used for various electronics devices such as wireless communication devices, cellular phones, laptop computers, personal digital assistants (PDAs), consumer electronics devices, etc. Integrated circuits may be fabricated with various IC process technologies depending on the digital and/or analog nature of the integrated circuits.

An IC fabrication process for an integrated circuit may be complex and may require many steps. These steps may be susceptible to manufacturing defects such as silicon defects, photo-lithography defects, mask contamination, IC process variations, defective oxide, etc. The manufacturing defects may cause electrical defects such as electrical shorts or opens (e.g., bridging faults), transistors stuck on open, changes in threshold voltage, etc. The electrical defects may in turn cause logical defects such as logic stuck at logic 1/0, slow transitions (e.g., delay faults), AND-bridging, OR-bridging, etc.

Various tests may be performed in order to ensure that only good integrated circuits are packaged and used. The tests may be performed at various stages of the manufacturing process to identify bad parts at each stage and to pass only good parts to the next stage of the manufacturing process. For example, scan tests may be performed on IC dies while on a wafer to detect for logical defects (e.g., stuck-at-faults) caused by manufacturing defects. A scan test typically passes input test data through a circuit being tested and compares output test data from the circuit against expected test data. IC dies that pass the scan tests may be packaged into ICs. Functional tests may then be performed on the packaged ICs, and ICs that pass the functional tests may be used in electronics devices.

Scan tests are useful to detect for manufacturing defects on IC dies but typically increase manufacturing costs. It is thus desirable to efficiently perform scan tests in order to reduce costs and obtain other benefits.

### SUMMARY

Techniques for efficiently performing scan tests are described herein. In an aspect, a single test pin may be used for both a scan input and a scan output of a scan chain on an IC die. A scan chain is a circuit used for scan testing. The multiplexing of the scan input and the scan output may reduce the number of test pins needed for scan testing of the IC die, which may then reduce costs and provide other benefits.

In one design, an apparatus may include a scan chain and an input/output (I/O) circuit. The scan chain may include at least one scan cell used for scan testing. The I/O circuit may be coupled between the scan chain and a single pad for a single test pin. The I/O circuit may multiplex a scan input and a scan output for the scan chain, provide the scan input from the pad to the scan chain during an input phase of a clock cycle, and provide the scan output from the scan chain to the pad during an output phase of the clock cycle.

In one design, the I/O circuit may include an input buffer and an output buffer. The input buffer may receive the scan input from the pad, provide the scan input to the scan chain when enabled, and provide a tri-state output when disabled. The output buffer may receive an output of the scan chain, provide the scan output to the pad when enabled, and provide a tri-state output when disabled. The input and output buffers may be enabled and disabled based on a bi-directional control signal, which may be received via another pad coupled to another test pin or may be generated internally.

The apparatus may include additional scan chains and additional I/O circuits. Each I/O circuit may multiplex a scan input and a scan output for an associated scan chain on an associated pad coupled to an associated test pin. The same bi-directional control signal may direct the I/O circuits to (i) provide the scan inputs from the pads to the associated scan chains during the input phase of the clock cycle and (ii) provide the scan outputs from the associated scan chains to the pads during the output phase of the clock cycle. The apparatus may be an IC die, a printed circuit board (PCB), etc.

Various aspects and features of the disclosure are described in further detail below.

### BRIEF DESCRIPTION OF THE DRAWINGS

FIG. 1 shows a tester and a wafer with multiple IC dies.

FIG. 2 shows a schematic diagram of a scan test structure.

FIG. 3 shows a schematic diagram of a scan test structure with multiplexed scan input and scan output on a single test pin.

FIG. 4 shows a timing diagram of a clock signal supporting scan pin multiplexing.

FIG. 5 shows a timing diagram of control and clock signals used for scan testing.

FIG. 6 shows input and output signals for scan cells and buffers in FIG. 3.

FIG. 7 shows scan testing with multiplexed scan inputs and outputs.

FIG. 8 shows a process for performing scan testing by an apparatus, e.g., an IC die.

FIG. 9 shows a process for performing scan testing by a tester.

### DETAILED DESCRIPTION

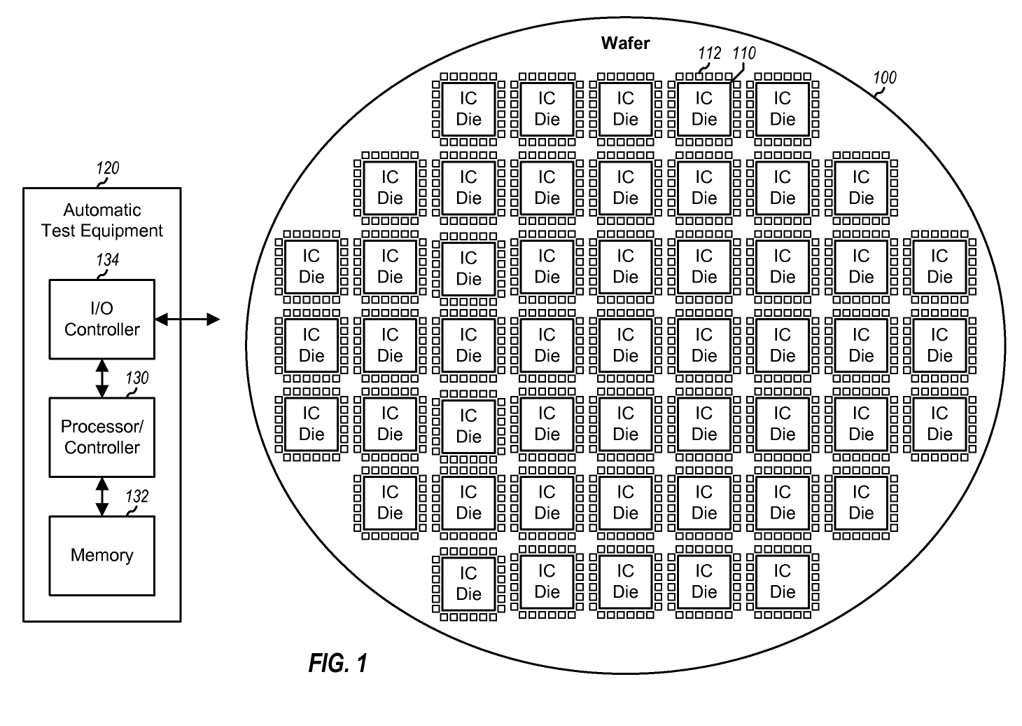

FIG. 1 shows a diagram of a wafer 100 that includes multiple IC dies 110. Each IC die 110 may have a number of pads 112 formed at the edges of the IC die. Pads 112 may be coupled to test pins during testing or to IC pins when packaged. The number of IC dies on a wafer may be dependent on various factors such as the size of the IC dies, the size of the wafer, the spacing between IC dies, etc. IC dies 110 may be designed to be identical but may observe different manufacturing defects. Scan tests may be performed on each IC die to identify bad IC dies with defects and to package only good IC dies without any detected defects.

Scan tests may be performed in parallel on multiple IC dies (which is commonly referred to as multi-site scan testing) in order to reduce costs. For scan testing, wafer 100 may be placed on a load board that may be accessed by an automatic test equipment (ATE) 120. ATE 120 may also be referred to as a tester. The load board may have a specific total number of test pins, which may be determined by the total number of test pins on ATE 120. The scan tests for each IC die may require a particular number of test pins, which may be dependent on the complexity of the IC die. The maximum number of IC dies that can be tested in parallel may then be determined by the total number of test pins on the load board and the number of test pins required for each IC die. In one specific design, the load board contains 672 total test pins, each IC die requires 84 test pins, and scan tests may be performed on eight IC dies in parallel. Other designs with different numerology are also possible.

An IC die may include one or more scan chains for scan testing. A scan chain may include sequential circuits and possibly combinatorial circuits, which may be representative of the actual sequential and combinatorial circuits used on the IC die. The number of scan chains to use for scan testing may be dependent on various factors such as the complexity of the IC die, the desired scan coverage, the number of test pins available for scan testing, etc. Faults detected in the scan chains may be indicative of manufacturing defects that may cause faults in the actual sequential and combinatorial circuits on the IC die.

ATE 120 may be used for scan testing of IC dies 110 in wafer 100. In the design shown in FIG. 1, ATE 120 includes a processor/controller 130, a memory 132, and an I/O controller 134. Processor/controller 130 may control scan testing of IC dies, provide test patterns for scan testing, etc. Memory 132 may store data and program codes for ATE 120. I/O controller 134 may receive test data from processor/controller 130 and may generate and send data, control, and clock signals to IC dies 110 for scan testing. I/O controller 134 may also receive data and control signals from IC dies 110 and may provide the received test data to processor/controller 130. Processor/controller 130 may compare the received test data against expected test data and may provide indications of detected faults on IC dies 110.

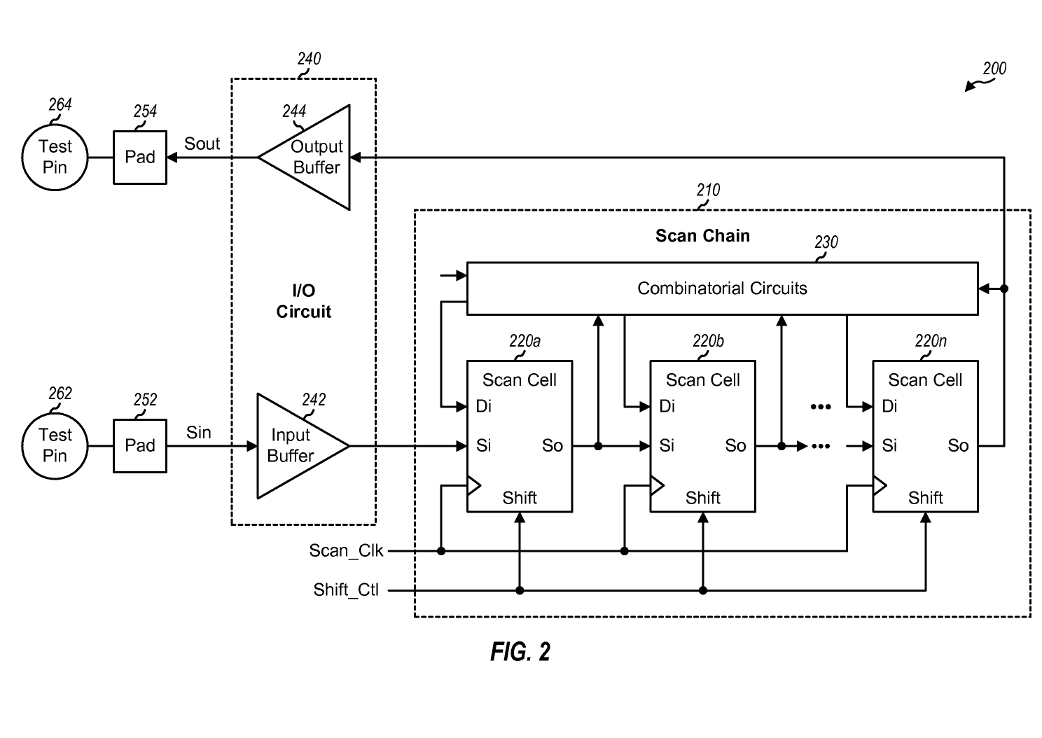

FIG. 2 shows a schematic diagram of a design of a scan test structure 200 comprising a scan chain 210 and an I/O circuit 240. In this design, scan chain 210 includes N scan cells 220a through 220n coupled in series, where in general N may be any integer value. A scan cell is a circuit used for scan testing and may be used as a basic building block for a scan chain. A scan cell may also be referred to as a scan register, a scan flop, etc. Each scan cell 220 may include a shift input (Si), a shift output (So), a data input (Di), a shift control input (Shift), and a clock input. The Di inputs and the So outputs of scan cells 220 may couple to combinatorial circuits 230, which may receive other inputs and/or provide other outputs.

For each scan cell 220, the Shift input may be set to logic high (‘1’) for a shift mode or to logic low (‘0’) for a capture mode. In the shift mode, a data value on the Si input may be passed to the So output on a rising edge of the scan clock. In the capture mode, a data value on the Di input may be captured and passed to the So output on a rising edge of the scan clock. The N scan cells 220a through 220n may be coupled in series. The same shift control (Shift_Ctl) signal may be applied to the Shift inputs of all N scan cells 220a through 220n. The same scan clock (Scan_Clk) signal may also be applied to the clock inputs of all scan cells. The Shift_Ctl signal may be set to (i) logic high to shift the Si data values through the scan cells or (ii) logic low to capture the Di data values by the scan cells.

In the design shown in FIG. 2, I/O circuit 240 includes an input buffer 242 and an output buffer 244. Buffer 242 receives a scan input (Sin) from an input pad 252 and drives the Si input of the first scan cell 220a. Buffer 244 receives the So output of the last scan cell 220n and provides a scan output (Sout) to an output pad 254.

FIG. 2 shows one scan chain that may be used on an IC die. The IC die may include a number of scan chains, and each scan chain may be implemented as shown in FIG. 2. In the design shown in FIG. 2, each scan chain utilizes two pads 252 and 254 that may be coupled to two test pins 262 and 264, respectively. If there are K scan chains on the IC die, then at least 2K test pins would be needed for scan testing of the IC die, where K may be any integer value.

In an aspect, the number of test pins needed for scan testing of an IC die may be reduced by multiplexing the scan input and scan output for a scan chain on a single test pin. This multiplexing may reduce the number of test pins needed for scan testing of the IC die. In particular, only K test pins may be used for scan testing of K scan chains on the IC die. This may allow more IC dies to be scan tested in parallel for a given total number of test pins on a tester, which may reduce test time as well as manufacturing costs.

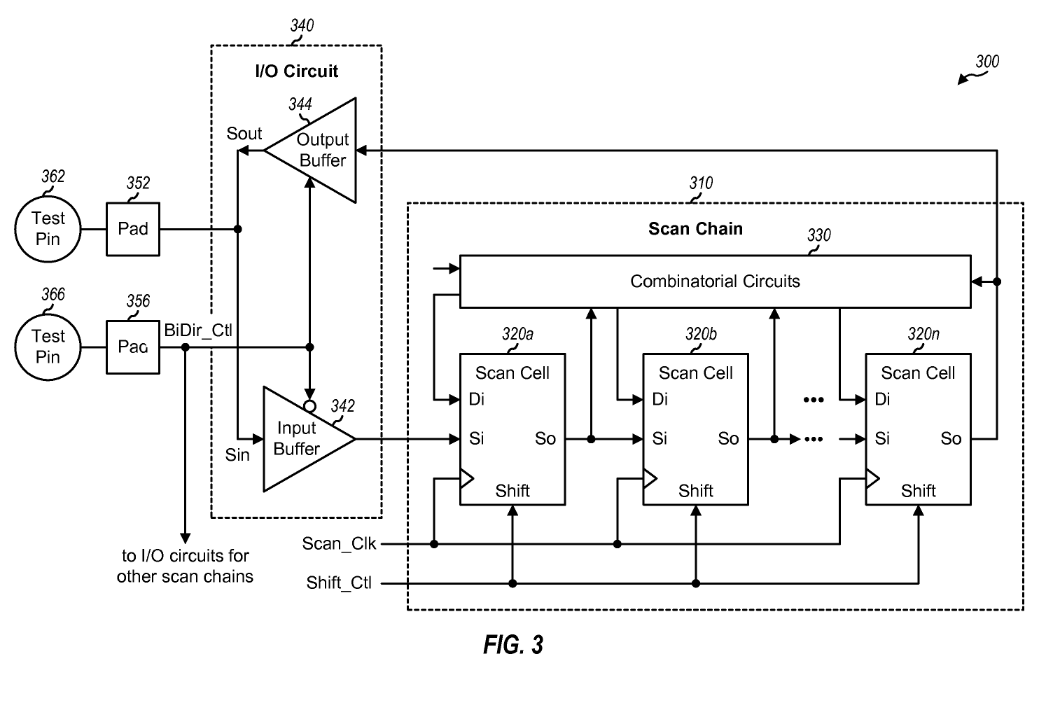

FIG. 3 shows a schematic diagram of a design of a scan test structure 300 comprising a scan chain 310 and an I/O circuit 340. In this design, scan chain 310 includes N scan cells 320a through 320n coupled in series and further to combinatorial circuits 330, as described above for scan cells 220a through 220n and combinatorial circuits 230 in FIG. 2. The same Shift_Ctl signal may be applied to the Shift inputs of all N scan cells 320a through 320n, and the same Scan_Clk signal may be applied to the clock inputs of all scan cells. The Shift_Ctl and Scan_Clk signals may be generated as described below.

In the design shown in FIG. 3, I/O circuit 340 includes a tri-state input buffer 342 and a tri-state output buffer 344. Buffer 342 receives a scan input (Sin) from a pad 352 and drives the Si input of the first scan cell 320a. Buffer 344 receives the So output of the last scan cell 320n and provides a scan output (Sout) to pad 352. Buffers 342 and 344 receive a bi-directional control (BiDir_Ctl) signal, which controls the multiplexing of the scan input and scan output on pad 352. In the design shown in FIG. 3, the BiDir_Ctl signal may be set to logic low to select the scan input path or to logic high to select the scan output path. When the scan input path is selected, input buffer 342 is enabled and provides the scan input from pad 352 to the first scan cell 320a, and output buffer 344 is disabled and placed in tri-state to avoid interfering with input buffer 342. Conversely, when the scan output path is selected, output buffer 344 is enabled and provides the scan output to pad 352, and input buffer 342 is disabled and placed in tri-state.

FIG. 3 shows one design of multiplexing the scan input and scan output on a single test pin. The bi-directional control signal may be generated by an external source (as shown in FIG. 3) or by internal logic based on event. FIG. 3 shows one design of an I/O circuit to multiplex the scan input and scan output. The I/O circuit may also be implemented with other glue logic that can appropriately handle and multiplex the scan input and scan output in each clock cycle.

FIG. 3 shows one scan chain that may be used on an IC die. The IC die may include a number of scan chains, and each scan chain may be implemented as shown in FIG. 3. In the design shown in FIG. 3, a scan chain utilizes a single pad 352 that may be coupled to a single test pin 362. K test pins may be used for K scan chains on the IC die. A test pin 366 may be coupled to a pad 356 and may provide the BiDir_Ctl signal, which may be sent to the I/O circuits for all K scan chains. Overhead for multiplexing the scan input and scan output on the same test pin may be as little as one additional test pin to provide the BiDir_Ctl signal. In another design, the BiDir_Ctl signal may be provided by internal logic, which may be programmed or loaded for scan testing. In this design, a test pin may not be needed to provide the BiDir_Ctl signal.

Scan cells 320 in FIG. 3 may be operated at a suitable clock rate such that sufficient timing margins can be obtained for both capturing the Sin signal from the tester and writing the Sout signal to the tester. In one design, scan cells 320 in FIG. 3 may be operated at the same or similar clock rate as scan cells 220 in FIG. 2, so that scan test time is not extended due to the multiplexing of the scan input and scan output on the same test pin.

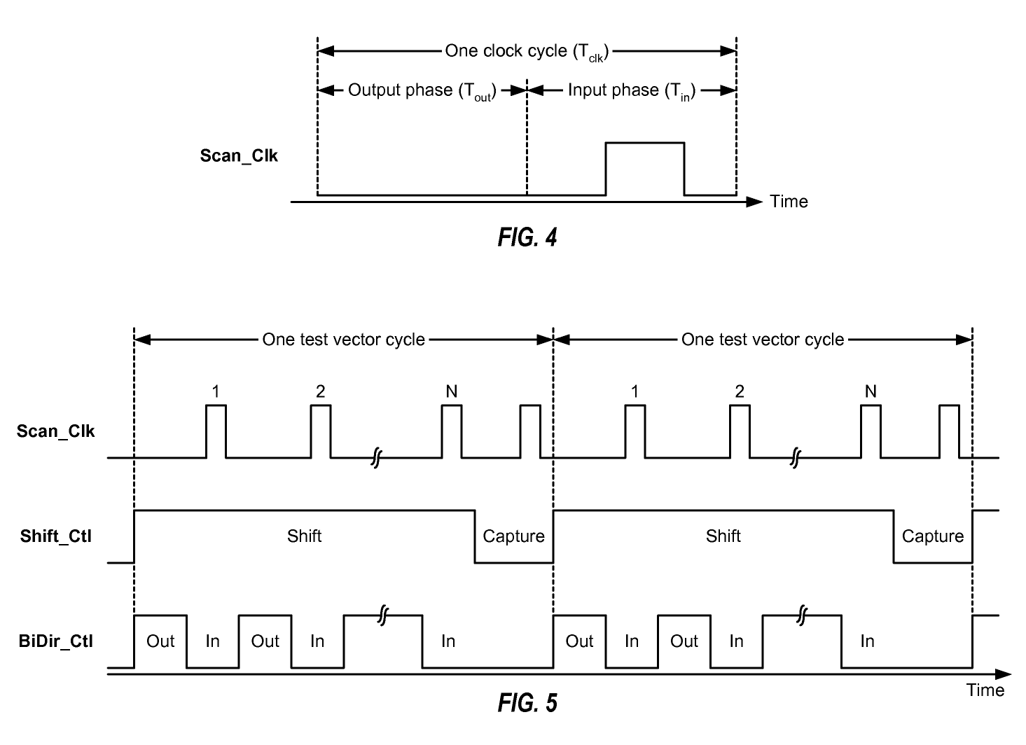

FIG. 4 shows a timing diagram of a design of partitioning a cycle of the scan clock to support multiplexing of the scan input and scan output on the same test pin. The duration of the clock cycle may be dependent on the clock rate and may be denoted as T_{clk}. The clock cycle may be partitioned into an input phase spanning Tᵢₙ seconds and an output phase spanning Tₒᵤₜ seconds, where T_{clk}=Tᵢₙ+Tₒᵤₜ. In the design shown in FIG. 4, the input phase includes both the rising and falling edges of the scan clock, which may be used to clock leading and trailing edge-triggered flip-flops in the scan cells. The scan clock may have less than 50% duty cycle, and the high pulse width may be less than T_{clk}/2. The output phase includes a portion of the clock cycle, which is of a sufficient duration to latch the Sout signal within the tester. In one specific design, the clock cycle duration is T_{clk}=40 nanoseconds (ns) for a 25 megaHertz (MHz) scan clock, the input phase duration is Tᵢₙ=28 ns, and the output phase duration is Tₒᵤₜ=12 ns. T_{clk}, Tᵢₙ and Tₒᵤₜ may also have other durations.

FIG. 5 shows a timing diagram of a design of the Scan_Clk, Shift_Ctl, and BiDir_Ctl signals for scan cells 320 in FIG. 3. In this design, the time line is partitioned into units of test vector cycles, with each test vector cycle covering N+1 clock cycles. In each test vector cycle, the Shift_Ctl signal is at logic high for N clock cycles to shift the Si data values through the N scan cells 320a through 320n and is then at logic low for one clock cycle to capture the Di data values by the N scan cells. The Scan_Clk signal includes N+1 clock cycles in each test vector cycle, with the first N clock cycles being used to shift the Si data values through the N scan cells and the last clock cycle being used to capture the Di data values by the N scan cells. In each of the first N clock cycles of each test vector cycle, the BiDir_Ctl signal toggles between (i) an output phase (denoted as “Out”) to read the So data value from the last scan cell 320n and (ii) an input phase (denoted as “In”) to write a new Si data value to the first scan cell 320a. The BiDir_Ctl signal remains at logic low for the last clock cycle of each test vector cycle.

FIG. 5 shows an example timing diagram for the control and clock signals for scan chain 310. In general, the Scan_Clk, Shift_Ctl, and BiDir_Ctl signals may be generated to achieve the desired shift and capture operations by the scan cells and to multiplex the scan input and scan output on the same test pin.

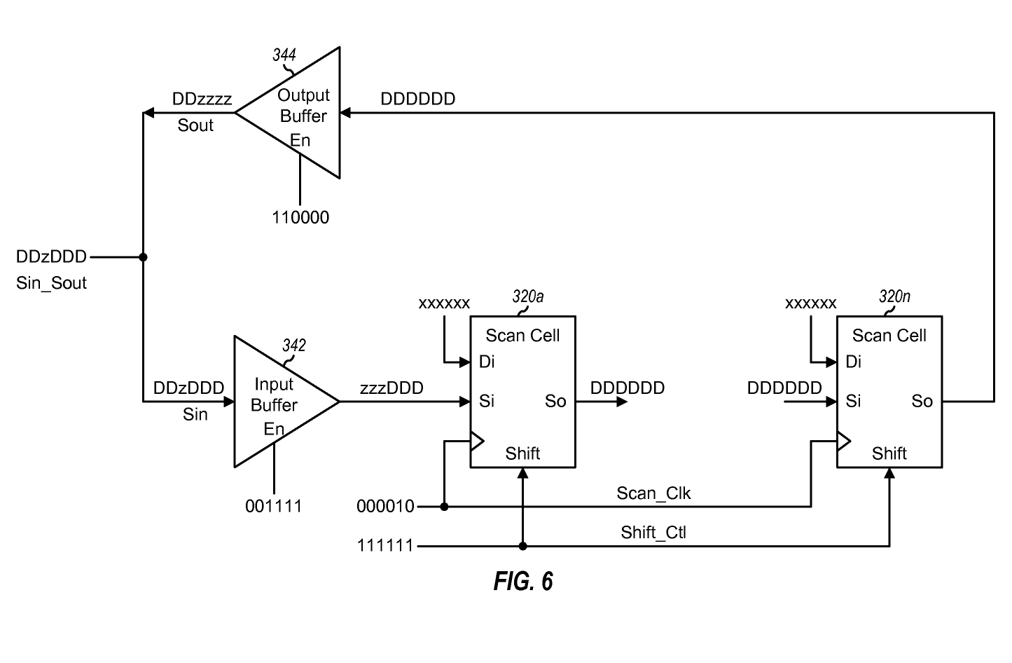

FIG. 6 shows input and output signals for the first scan cell 320a, the last scan cell 320n, input buffer 342, and output buffer 344 in FIG. 3 for one clock cycle. In FIG. 6, the clock cycle is partitioned into six parts. Each input or output signal during this clock cycle is denoted as yyyyyy, where each “y” is a value for one part of the clock cycle. In particular, “y” may be equal to “D” for a data value, “z” for tri-state, “x” for don't care, “1” for logic high, or “0” for logic low.

In the example shown in FIG. 6, the BiDir_Ctl signal is equal to 110000, output buffer 344 is enabled for the first two parts of the clock cycle and is tri-stated for the last four parts of the clock cycle. Input buffer 342 is tri-stated for the first two parts of the clock cycle and is enabled for the last four parts of the clock cycle. The Scan_Clk signal is equal to 000010, has a duty cycle of approximately 17%, and has a high pulse during the fifth part of the clock. The Shift_Ctl signal is equal to 111111 to select the shift mode.

The tester provides an input signal of zzzDDD, which is combined with an Sout signal of DDzzzz from output buffer 344 to obtain an Sin signal of DDzDDD for input buffer 342. Buffer 342 is enabled for the last four parts of the clock cycle and thus provides an output signal of zzzDDD. Scan cell 320a receives an input signal of zzzDDD from buffer 342 and latches the input signal at the start of the fifth part with the 000010 clock signal. Scan cell 320n similarly latches its input signal at the start of the fifth part of the clock cycle and provides an output signal of DDDDDD to buffer 344. Buffer 344 is enabled for the first two parts of the clock cycle and thus provides an output signal of DDzzzz. As shown by the example in FIG. 6, the scan input and scan output can be multiplexed on the same test pin to obtain an Sin_Sout signal composed of the Sin signal provided to input buffer 342 and the Sout signal provided by output buffer 344.

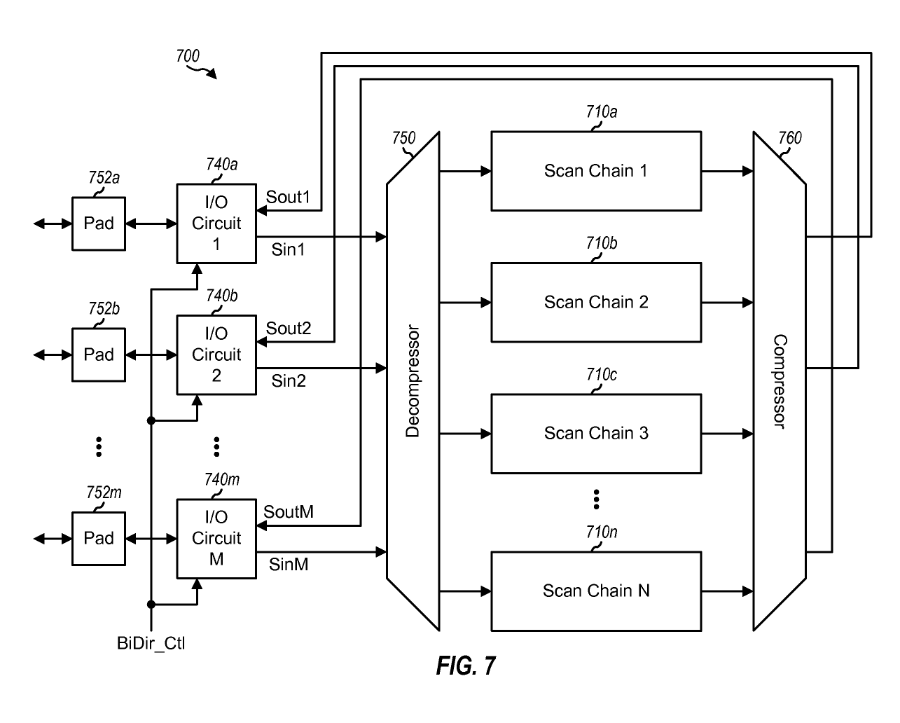

FIG. 7 shows a block diagram of a design of a scan test circuit 700 with multiplexed scan inputs and scan outputs on the same test pins. In this design, M I/O circuits 740a through 740m may be coupled to M pads 752a through 752m, respectively, which may be further coupled to M test pins (not shown in FIG. 7), where M may be any integer value. A decompressor 750 may receive input test data via I/O circuits 740a through 740m, decompress the input test data, and provide decompressed test data to N scan chains 710a through 710n, where N is typically larger than M. Decompressor 750 may be implemented in different manners depending on the technique used to compress the input test data. Each scan chain 710 may operate on the decompressed test data for that scan chain. A compressor 760 may receive uncompressed test data from scan chains 710a through 710n, compress the uncompressed test data, and provide output test data to I/O circuits 740a through 740m. Compressor 760 may be implemented with exclusive-OR (XOR) logic that can combine outputs from multiple scan chains. Each I/O circuit 740 may receive input test data from one test pin and provide output test data to the same test pin.

In the design shown in FIG. 7, scan testing may be performed in accordance with a test sequence comprising: scan input, decompressor, scan chains, compressor, and scan output. The scan inputs and scan outputs may be multiplexed in each clock cycle to obtain various benefits described below.

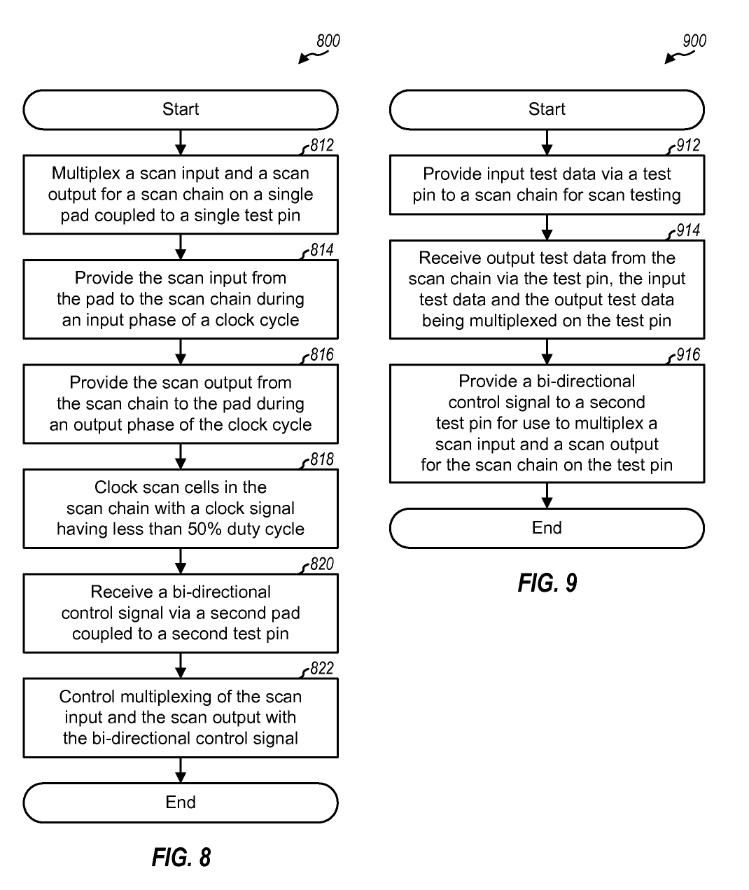

FIG. 8 shows a design of a process 800 for performing scan testing. Process 800 may be performed by an apparatus such as an IC die, a PCB, etc. A scan input and a scan output for a scan chain may be multiplexed on a single pad coupled to a single test pin (block 812). The scan input may be provided from the pad to the scan chain during an input phase of a clock cycle (block 814). The scan output may be provided from the scan chain to the pad during an output phase of the clock cycle (block 816). In one design of block 814, the scan input from the pad may be buffered. The buffered scan input may be provided to the scan chain during the input phase, and a tri-state output may be provided to the scan chain during the output phase. In one design of block 816, an output of the scan chain may be buffered to obtain the scan output. The scan output may be provided to the pad during the output phase, and a tri-state output may be provided to the pad during the input phase. In one design, scan cells in the scan chain may be clocked with a clock signal having less than 50% duty cycle (block 818).

A bi-directional control signal may be received via a second pad coupled to a second test pin (block 820). The multiplexing of the scan input and the scan output may be controlled with the bi-directional control signal (block 822). In one design, a first version of the bi-directional control signal may be used to provide the scan input from the pad to the scan chain. A second version of the bidirectional control signal may be used to provide the scan output from the scan chain to the pad. The first version may be complementary of the second version.

Multiple scan chains and multiple I/O circuits may be used for scan testing, e.g., as shown in FIG. 7. A scan input and a scan output for each scan chain may be multiplexed on an associated pad coupled to an associated test pin. The same bi-directional control signal may be used to multiplex the scan inputs and the scan outputs for all scan chains.

FIG. 9 shows a design of a process 900 for performing scan testing. Process 900 may be performed by a tester such as ATE 120 in FIG. 1 or by some other entity. Input test data may be provided via a test pin to a scan chain for scan testing (block 912). Output test data may be received from the scan chain via the test pin, with the input test data and the output test data being multiplexed on the same test pin (block 914). In one design of block 912, an input data value may be provided to the test pin during an input phase of a clock cycle. In one design of block 914, an output data value may be received from the test pin during an output phase of the clock cycle. A bi-directional control signal may be provided to a second test pin and used to multiplex a scan input and a scan output for the scan chain on the test pin (block 916).

In one design, multi-site scan testing may be performed, and input test data may be provided via multiple test pins to multiple scan chains on multiple IC dies for concurrent scan testing of these IC dies. Output test data may be received from the multiple scan chains via the multiple test pins for the scan testing. The input test data and the output test data for each scan chain may be multiplexed on a single test pin for that scan chain.

The techniques described herein may be used for both full pin scan and XOR-based compression architecture designs. For full pin scan, the output test data from all scan chains may be captured and analyzed to detect for faults. For XOR-based compression, the output test data from different scan chains may be combined with XOR logic to obtain compressed output test data, which may be analyzed to detect for faults. The output test data for both full pin scan and XOR-based compression designs may be obtained via test pins that multiplex scan inputs and scan outputs.

The techniques described herein may provide various advantages. First, the techniques may reduce the number of test pins needed for scan testing of an IC die. Up to twice as many IC dies may be concurrently scan tested for multi-site testing. The techniques may reduce scan test time for a wafer since more IC dies can be tested in parallel, which may then reduce the number of scan tests to repeat for the wafer. Second, the techniques may support scan testing of IC dies with more and possibly more complex processing cores (e.g., multiple cores of the same type). These more complex IC dies may be scan tested without extending test time. Third, if more scan chains are configured, then a compressor may be more shallow in logic depth, and diagnosis may be more accurate due to fewer stumps feeding each scan output pin. Fourth, the number of available scan pins may be doubled by using each test pin for both a scan input pin and a scan out pin. Multiple compressors may be supported with more available scan pins, which may be partitioned to integrate more processor cores with independent compressors.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the disclosure herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the scope of the disclosure. Thus, the disclosure is not intended to be limited to the examples and designs described herein but is to be accorded the widest scope consistent with the principles and novel features disclosed herein.

What is claimed is:

1. An apparatus comprising:
a scan chain comprising at least one scan cell used for scan testing; and
an input/output (I/O) circuit coupled between the scan chain and a single pad for a single test pin, the I/O circuit operative to multiplex a scan input and a scan output for the scan chain in a clock cycle, to provide the scan input from the pad to the scan chain, and to provide the scan output from the scan chain to the pad.

2. The apparatus of claim 1, wherein the I/O circuit comprises
a first buffer operative to receive the scan input from the pad, to provide the scan input to the scan chain when the first buffer is enabled, and to provide a tri-state output when the first buffer is disabled, and
a second buffer operative to receive an output of the scan chain, to provide the scan output to the pad when the second buffer is enabled, and to provide a tri-state output when the second buffer is disabled.

3. The apparatus of claim 2, wherein the first buffer is enabled and disabled based on a first version of a bi-directional control signal, wherein the second buffer is enabled and disabled based on a second version of the bi-directional control signal, and wherein the first version is complementary of the second version.

4. The apparatus of claim 3, wherein the bi-directional control signal is received via a second pad coupled to a second test pin.

5. The apparatus of claim 1, wherein the I/O circuit provides the scan input from the pad to the scan chain during an input phase of the clock cycle and provides the scan output from the scan chain to the pad during an output phase of the clock cycle.

6. The apparatus of claim 1, wherein the at least one scan cell is triggered with a clock signal having less than 50% duty cycle.

7. The apparatus of claim 1, further comprising:
at least one additional scan chain used for scan testing; and
at least one additional I/O circuit coupled between the at least one additional scan chain and at least one additional pad coupled to at least one additional test pin, each additional I/O circuit configured to multiplex a scan input and a scan output for an associated scan chain on an associated pad.

8. The apparatus of claim 7, wherein a common bi-directional control signal directs the I/O circuits to provide scan inputs from the pads to the associated scan chains during an input phase of the clock cycle and to provide scan outputs from the associated scan chains to the pads during an output phase of the clock cycle.

9. An integrated circuit (IC) comprising:
a scan chain comprising at least one scan cell used for scan testing; and
an input/output (I/O) circuit coupled between the scan chain and a single pad for a single test pin, the I/O circuit operative to multiplex a scan input and a scan output for the scan chain in a clock cycle, to provide the scan input from the pad to the scan chain, and to provide the scan output from the scan chain to the pad.

10. The integrated circuit of claim 9, wherein the I/O circuit comprises
a first buffer operative to receive the scan input from the pad, to provide the scan input to the scan chain when the first buffer is enabled, and to provide a tri-state output when the first buffer is disabled, and
a second buffer operative to receive an output of the scan chain, to provide the scan output to the pad when the second buffer is enabled, and to provide a tri-state output when the second buffer is disabled.

11. A method of performing scan testing, comprising:
multiplexing a scan input and a scan output for a scan chain on a single pad coupled to a single test pin;
providing the scan input from the pad to the scan chain during an input phase of a clock cycle; and
providing the scan output from the scan chain to the pad during an output phase of the clock cycle.

12. The method of claim 11, wherein the providing the scan input comprises
buffering the scan input from the pad,
providing the buffered scan input to the scan chain during the input phase, and
providing a tri-state output to the scan chain during the output phase.

13. The method of claim 11, wherein the providing the scan output comprises
buffering an output of the scan chain to obtain the scan output,
providing the scan output to the pad during the output phase, and
providing a tri-state output to the pad during the input phase.

14. The method of claim 11, further comprising:
receiving a bi-directional control signal via a second pad coupled to a second test pin;
using a first version of the bi-directional control signal to provide the scan input from the pad to the scan chain; and
using a second version of the bi-directional control signal to provide the scan output from the scan chain to the pad, the first version being complementary of the second version.

15. The method of claim 11, further comprising:
clocking at least one scan cell in the scan chain with a clock signal having less than 50% duty cycle.

16. The method of claim 11, further comprising:
multiplexing a scan input and a scan output for each of at least one additional scan chain on an associated one of at least one additional pad coupled to at least one additional test pin.

17. An apparatus for performing scan testing, comprising:
means for multiplexing a scan input and a scan output for a scan chain on a single pad coupled to a single test pin;
means for providing the scan input from the pad to the scan chain during an input phase of a clock cycle; and
means for providing the scan output from the scan chain to the pad during an output phase of the clock cycle.

18. The apparatus of claim 17, wherein the means for providing the scan input comprises
means for buffering the scan input from the pad,
means for providing the buffered scan input to the scan chain during the input phase, and
means for providing a tri-state output to the scan chain during the output phase.

19. The apparatus of claim 17, wherein the means for providing the scan output comprises
means for buffering an output of the scan chain to obtain the scan output,
means for providing the scan output to the pad during the output phase, and
means for providing a tri-state output to the pad during the input phase.

20. The apparatus of claim 17, further comprising:
means for receiving a bi-directional control signal via a second pad coupled to a second test pin;
means for using a first version of the bi-directional control signal to provide the scan input from the pad to the scan chain; and
means for using a second version of the bi-directional control signal to provide the scan output from the scan chain to the pad, the first version being complementary of the second version.

21. A method of performing scan testing, comprising:
providing input test data via a test pin to a scan chain for scan testing; and
receiving output test data from the scan chain via the test pin, the input test data and the output test data being multiplexed on the test pin in a clock cycle.

22. The method of claim 21, wherein the providing the input test data comprises providing an input data value to the test pin during an input phase of the clock cycle, and wherein the receiving the output test data comprises receiving an output data value from the test pin during an output phase of the clock cycle.

23. The method of claim 21, further comprising:
providing a bi-directional control signal to a second test pin, the bi-directional control signal multiplexing a scan input and a scan output for the scan chain on the test pin.

24. The method of claim 21, further comprising:
providing the input test data via a plurality of test pins to a plurality of scan chains on a plurality of integrated circuit (IC) dies for concurrent scan testing of the plurality of IC dies; and
receiving output test data from the plurality of scan chains via the plurality of test pins, the input test data and the output test data for each scan chain being multiplexed on a single test pin for the scan chain.

25. An apparatus for performing scan testing, comprising:
means for providing input test data via a test pin to a scan chain for scan testing; and
means for receiving output test data from the scan chain via the test pin, the input test data and the output test data being multiplexed on the test pin in a clock cycle.

26. The apparatus of claim 25, wherein the means for providing the input test data comprises means for providing an input data value to the test pin during an input phase of the clock cycle, and wherein the means for receiving the output test data comprises means for receiving an output data value from the test pin during an output phase of the clock cycle.

27. The apparatus of claim 25, further comprising:
means for providing a bi-directional control signal to a second test pin, the bi-directional control signal multiplexing a scan input and a scan output for the scan chain on the test pin.

28. The apparatus of claim 25, further comprising:
means for providing the input test data via a plurality of test pins to a plurality of scan chains on a plurality of integrated circuit (IC) dies for concurrent scan testing of the plurality of IC dies; and
means for receiving output test data from the plurality of scan chains via the plurality of test pins, the input test data and the output test data for each scan chain being multiplexed on a single test pin for the scan chain.

29. An apparatus comprising:
at least one processor configured to provide input test data via a test pin to a scan chain for scan testing, and to receive output test data from the scan chain via the test pin, the input test data and the output test data being multiplexed on the test pin in a clock cycle.

30. The apparatus of claim 29, wherein the at least one processor is configured to provide an input data value to the test pin during an input phase of the clock cycle, and to receive an output data value from the test pin during an output phase of the clock cycle.

31. The apparatus of claim 29, wherein the at least one processor is configured to provide a bi-directional control signal to a second test pin, the bi-directional control signal multiplexing a scan input and a scan output for the scan chain on the test pin.

32. The apparatus of claim 29, wherein the at least one processor is configured to provide the input test data via a plurality of test pins to a plurality of scan chains on a plurality of integrated circuit (IC) dies for concurrent scan testing of the plurality of IC dies, and to receive output test data from the plurality of scan chains via the plurality of test pins, the input test data and the output test data for each scan chain being multiplexed on a single test pin for the scan chain.

33. A computer program product, comprising:
a computer-readable medium comprising:
code for causing at least one computer to provide input test data via a test pin to a scan chain for scan testing, and
code for causing the at least one computer to receive output test data from the scan chain via the test pin, the input test data and the output test data being multiplexed on the test pin in a clock cycle.
